(19) United States
(12) Patent Application Publication
(10) Pub. No.: US 2005/0121141 A1
(43) Pub. Date: Jun. 9, 2005

(54) Real time process control for a polishing process

(76) Inventor: Antoine P. Manens, Mountain View, CA (US)

Correspondence Address: MOSER, PATTERSON & SHERIDAN, LLP/;APPLIED MATERIALS, INC., 3040 POST OAK BOULEVARD, SUTIE 1500, HOUSTON, TX, 77056, US

(21) Appl. No.: 10/987,795

(22) Filed: Nov. 12, 2004

Related U.S. Application Data
(60) Provisional application No. 60/519,666, filed on Nov. 13, 2003.

(51) Int. Cl. G01N 27/72; G01R 33/00; C23F 1/00; H01L 21/306; H01L 21/461

(52) U.S. Cl. 156/345.15; 438/692

(57) ABSTRACT

Embodiments of the invention provide a fluid processing system for substrates. The processing system includes a processing cell and a substrate inspection station. During a processing sequence, a substrate is first inspected in the inspection station. The information from the inspection is then fed forward and used to control the operation of the fluid processing cell.

### CROSS-REFERENCE TO RELATED APPLICATIONS

This application claims benefit of U.S. provisional patent application Ser. No. 60/519,666, filed Nov. 13, 2003, which is herein incorporated by reference.

### BACKGROUND OF THE INVENTION

1. Field of the Invention

The present invention generally relates to a method for processing a substrate using a feed forward control scheme. More particularly, embodiments of the invention relate to using a substrate inspection station to measure a parameter of a substrate prior to initiating a processing step, and further, using the parameter measurement as an input to control the processing step.

2. Description of the Related Art

Eddy current sensors are non-contact measurement devices used for measuring the thickness of conductive objects. Briefly, an eddy current sensor includes a sensor coil, which when driven by an AC current, generates an oscillating magnetic field that induces an eddy current in a nearby conductive object. The magnitude of the induced eddy current, generally expressed in mA, is dependent on the strength or flux of the magnetic field created by the AC current and the impedance of the object. The impedance of the conductive object is known to be related to the resistivity of the object, and as such, the thickness of the object may be determined from the known resistivity of the object and the measured eddy current or impedance.

In semiconductor processing, one common use of eddy current sensors is for measuring the thickness of a conductive layer (such as, e.g., a copper layer) deposited on a substrate (or a layer formed onto the substrate). Eddy current sensors are also used for determining the thickness of a conductive layer at various sampling locations on the substrate. In many cases, it is important to have a generally uniform conductive layer thickness to avoid problems in subsequent processing, such as etching, polishing, formation of additional layers, etc. It is accordingly important to be able to accurately determine the thickness of conductive layers so that corrective action may be taken, if needed, to obtain a desired uniform thickness. Alternatively, the substrate can be scrapped to avoid the unnecessary expense of further processing.

Currently available eddy current sensor devices for measuring the thickness of conductive layers on substrates are generally very slow. These devices can also be very sensitive to inadvertent movement of the object relative to the eddy current sensors and, accordingly, often have complex and costly position control mechanisms in an attempt to provide a generally uniform distance between the sensor and the substrate.

### SUMMARY OF THE INVENTION

Embodiments of the invention provide a fluid processing system for substrates. The processing system includes a processing cell and a substrate inspection station. During a processing sequence, a substrate is first inspected in the inspection station. The information from the inspection is then fed forward and used to control the operation of the fluid processing cell.

Embodiments of the invention further provide methods and apparatus for measuring the thickness of a test object, such as a portion of a conductive layer deposited on a substrate. An apparatus in accordance with one or more embodiments of the invention includes an eddy current sensor having first and second sensor heads positioned on one or both sides of the substrate being measured.

The sensor heads are positioned to have a predetermined gap therebetween for passage by at least a portion of the test object through the gap. The sensor heads make measurements at given sampling locations on the test object when at the gap. The apparatus also includes a position sensing mechanism to determine positions of the sampling locations on the test object. The apparatus also includes an evaluation circuit in communication with the eddy current sensor and with the position sensing mechanism for determining the thickness of the test object at the sampling locations. The apparatus can also include a mechanism for moving the test object through the gap while the measurements are made.

In accordance with one or more embodiments of the invention, the apparatus also includes a displacement sensor for detecting any displacement of the test object in a direction generally extending between the first and second sensor heads. The displacement sensor is in communication with the evaluation circuit, which adjusts the measurements of the sensor heads to compensate for any detected displacement of the test object.

A method in accordance with one or more embodiments of the invention includes making measurements at sampling locations on the test object using first and second eddy current sensor heads positioned on opposite sides of the test object. The method also includes determining the positions of the sampling locations on the test object, and calculating the thickness of the test object at the sampling locations. The test object can be moved relative to the sensor heads while making the measurements.

In accordance with one or more embodiments of the invention, the method also includes the step of detecting any displacement of the test object in a direction generally extending between the first and second sensor heads. The measurements can then be adjusted to compensate for any detected displacement of the test object.

These and other features will become readily apparent from the following detailed description wherein embodiments of the invention are shown and described by way of illustration. As will be realized, the invention is capable of other and different embodiments and its several details may be capable of modifications in various respects, all without departing from the invention. Accordingly, the drawings and description are to be regarded as illustrative in nature and not in a restrictive or limiting sense.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a representative eddy current sensor head.

FIG. 2 is a block diagram of an apparatus for measuring the thickness of an object in accordance with one or more embodiments of the invention.

FIG. 3 is a perspective view of certain components of the FIG. 2 apparatus.

FIG. 4 is a schematic illustration of representative flux lines of a single eddy current sensor in accordance with the prior art.

FIG. 5 is a schematic illustration of representative flux lines of the dual eddy current sensor heads of the FIG. 2 apparatus.

FIG. 6 is a graph illustrating the reduced sensitivity of an apparatus in accordance with one or more embodiments of the invention to changes in the distance between the test object and the eddy current sensor heads.

FIG. 7 is a graph illustrating representative values for distance compensation factors in accordance with one or more embodiments of the invention.

FIG. 8 is a flow chart illustrating a process for measuring the thickness of an object in accordance with one or more embodiments of the invention.

FIG. 9 illustrates a top plan view of an exemplary ECP system.

FIG. 10 illustrates a perspective view of an exemplary substrate inspection station.

FIG. 11 illustrates a perspective view of another exemplary substrate inspection station.

FIG. 12 illustrates an embodiment of the invention where an inspection station is implemented onto a substrate polishing system.

FIG. 13 illustrates an embodiment of a process cell that may be advantageously used on a polishing system of the invention.

### DETAILED DESCRIPTION OF THE PREFERRED EMBODIMENT

The present invention is generally directed to an on-the-fly eddy current sensor device for rapidly and accurately determining the thickness of a test object at various sampling locations on the object. More particularly, the present invention is directed to implementing a conductive layer thickness sensor into a polishing or deposition process via measurement of the thickness of a layer prior to polishing/deposition, and then controlling the polishing/deposition in accordance with the measurement. Briefly, the device includes an eddy current sensor having two opposed heads that are spaced apart by a predetermined gap. During use, a portion of the test object is moved through or into the gap, and the thickness of the test object is determined at various sampling locations on the test object, preferably while the test object is being moved. The device also includes a set of position sensors, which can be used to determine the position of the sampling locations relative to the test object when measurements are made.

Using two eddy current sensor heads on opposite sides of the test object improves the accuracy of measurements because the device is significantly less sensitive to inadvertent movement or vibration of a given sampling location toward or away from the sensor heads resulting from passage of the test object through the gap. The measurements can be made on-the-fly, allowing multiple sampling locations to be quickly measured.

One or more embodiments of the present invention contemplate the inclusion of a Z-position displacement sensor to determine the distance between the test object and the sensor heads in order to determine any distance related compensation factor to be applied to the raw data to compensate for distance and vibration effects to even further improve measurement accuracy.

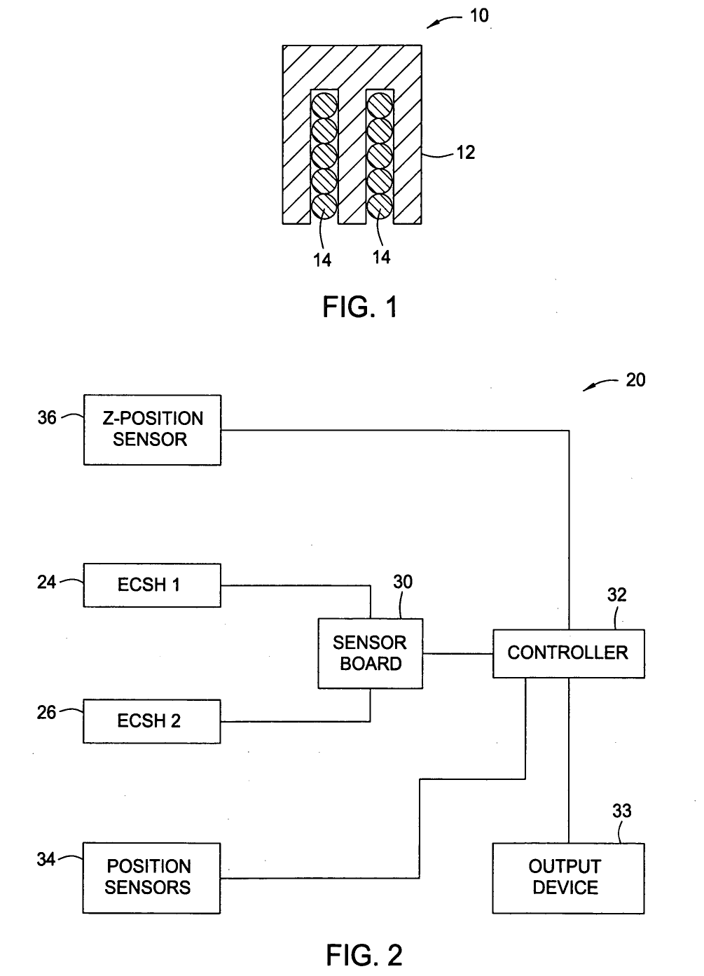

FIG. 1 schematically illustrates a representative eddy current sensor head 10 that can be used in a thickness measurement device in accordance with various embodiments of the invention. The eddy current sensor head 10 includes a pot core 12 and a coil 14. By way of example, the core 12 can be a split ferrite pot core. The core 12 can, e.g., have a diameter of about 9 mm and a height of about 4 mm. Cores having other configurations and sizes can also be used. By way of example, the coil 14 can comprise 26-32 gauge wire and have about 10-30 turns. Other wire sizes and coil configurations can also be used.

The sensor coil 14, when driven by an AC current, generates an oscillating magnetic field that induces an eddy current in the surface of the test object. The eddy current is dependent on the strength of the magnetic B-field created by the AC current and the impedance of the object, which is related to the thickness of the object and the resistivity of the object. The thickness of the object can accordingly be determined based on the known resistivity of the object and the eddy current detected by the sensor coil.

Other types of eddy current sensor heads can also be used. These include, e.g., sensor heads with two coils, in which a primary coil is driven by an AC current and generates an oscillating magnetic field, and a secondary pickup coil receives a responsive signal from the test object.

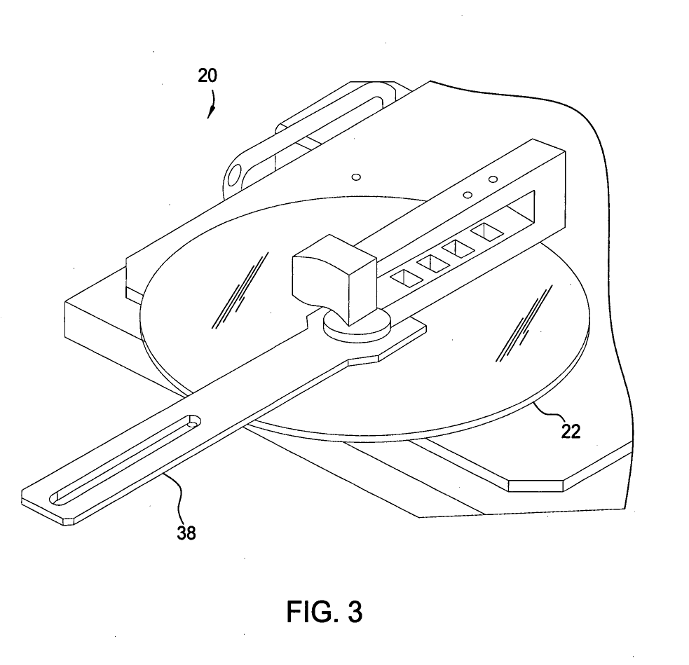

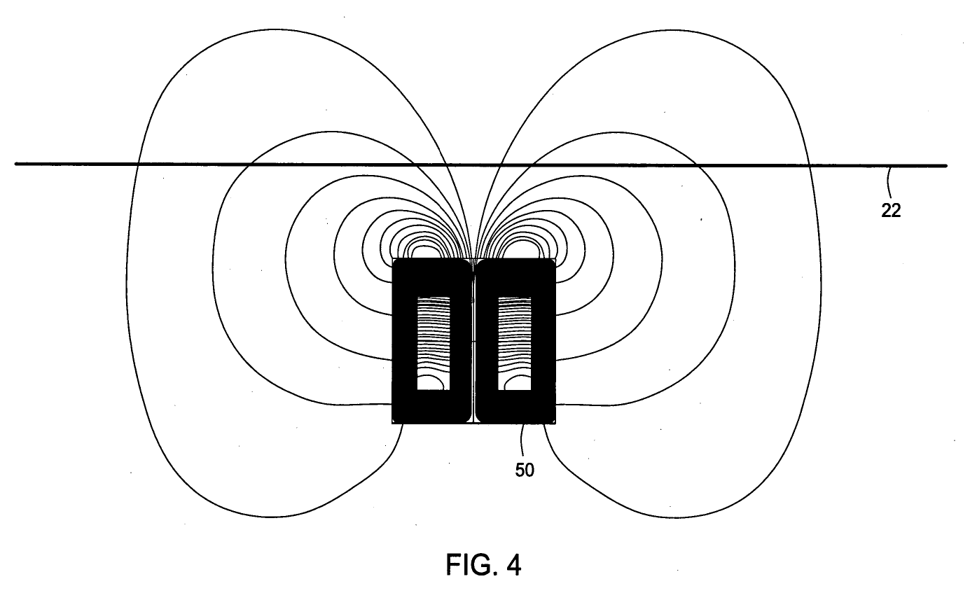

FIG. 2 is a representative block diagram of an apparatus 20 for measuring the thickness of a test object in accordance with one or more embodiments of the invention. FIG. 3 is a perspective view of some elements of the apparatus 20. Referring now to FIGS. 2 and 3, the apparatus 20 includes an eddy current sensor, which has two sensor heads 24, 26 that can be connected in either a serial or parallel circuit. The sensor heads 24, 26 are mounted on respective brackets 28 such that they are spaced a predetermined distance from each other, forming a gate or gap therebetween. The gate distance can be varied depending on the size of the test object being measured. A typical range for use, e.g., in semiconductor manufacturing for measuring the thickness of layers deposited on substrates, can be between about 2-6 mm. Such a range has been found to provide suitable spot size, signal strength and handling reliability in typical semiconductor processing applications.

The eddy current sensor heads 24, 26 can be connected to a sensor board circuit 30, which generates the AC current for driving the sensor heads 24, 26 and which receives a pickup eddy current signal from the sensor heads 24, 26 indicative of the test object thickness. The pickup eddy current signal with voltage form is transmitted to a controller 32, which can include an analog to digital converter for converting the pickup signal to a digital signal for processing as will be described below.

The AC current used to drive the coils can vary. By way of example, the driving current can be at frequencies between about 300 kHz and 5 MHz. Other current values are also possible.

The device 20 also includes an array of position sensors 34, which detect the position of the test object 22 as it is moved through the gap between the eddy current sensor heads 24, 26. The position sensors 34 are connected to the controller 32, which can determine the sampling locations on the test object 22 when thickness measurements are made. One example of a position sensor that can be used in the array is an optical sensor such as a through-beam type sensor. Examples of suitable position sensors include the model EX-11 sensor commercially available from SUNX of Japan.

To further increase measurement accuracy, one or more embodiments of the present invention contemplate the inclusion of a Z-position sensor 36 to measure the distance between the test object 22 and the sensor heads 24, 26 in order to determine any distance related compensation factor that can be applied to the raw data to compensate for distance and vibration effects. One example of a suitable Z-position sensor is a laser distance sensor. An example of such a sensor is the model XZ-30V sensor commercially available from OMRON of Japan.

The controller 32 computes the thickness of the test object 22 at the various sampling locations based on respective readings from the sensors. A representative controller 32 can include an analog to digital converter, a PLC (Programmable Logic Control) and a PC (personal computer). The analog to digital converter converts analog signals from the eddy current sensor and the Z-position sensor to digital form for processing. The PLC receives sensing signals from the sensors and performs data logging or collection functions. The PC receives data from the PLC and performs measurement and compensation calculations. The measurement results can be output to an output device 33 such as, e.g., a computer display or printer.

Various known methods can be used for computing the thickness of the test object from the eddy current sensor readings. For example, one such known method uses empirical data of eddy current sensor readings taken of particular test objects having known thicknesses to generate sensor reading calibration curves. In use of the device, eddy current sensor readings can be mapped to the calibration curves to determine the thickness of measured test objects.

By way of example, operation of the device 20 is now described for determining the thickness of a conductive layer on a substrate substrate 22. The substrate 22 is positioned on an end effector 38 connected to a robotic arm. The robotic arm is then actuated to move the substrate through the gate formed by the pair of eddy current sensor heads 24, 26. As the substrate 22 moves through the gate, it passes the array of position sensors 34, which are successively tripped or actuated by the leading edge of the substrate 22. A sensing routine is triggered when the substrate 22 passes the first position sensor 34. The sensing routine can include the eddy current sensor taking periodic thickness readings (e.g., at a sampling rate of 1,000 readings/second), and the position sensors 34 detecting when the substrate edge passes each successive sensor to determine the velocity of the substrate. Using this information, the controller 32 can determine the measured thickness at each sampling location and the position of each sampling location on the substrate. In this manner, thickness measurements can be taken along a given line extending across the substrate. Measurements along different lines across the substrate can be taken, if desired, by rotating the substrate to a desired position and then moving it through the device 20 while making measurements.

The device preferably makes measurements on the fly, i.e., while the substrate is being moved through the gap between the sensor heads. High sampling rates are possible, allowing the substrate thickness to be quickly measured. For example, and in accordance with one or more embodiments of the invention, a substrate having a diameter of about 300 mm can be measured in about two seconds, at about 2,000 sampling points. Other sampling rates can also be used.

By using two eddy current sensor heads on opposite sides of the test object, inadvertent movement of a given sampling location toward or away from the sensor heads (resulting from movement of the test object through the gap) does not significantly affect the measurement. Accordingly, more accurate measurements can be made at each sampling location. Also, the need for extensive positioning control mechanisms is avoided, and the measurements can be made more quickly. The sensor readings can be continually made as the test object moves through the gap between the eddy current sensor heads.

By making quick and accurate measurements of the thickness of the conductive layer on the substrate, corrective action can be taken, if needed, to obtain a desired thickness. For example, if a generally uniform thickness is desired and the measurements indicate that the thickness is not sufficiently uniform, the substrate can be subjected to selective chemical mechanical polishing or other processes to obtain the desired uniform thickness.

FIG. 4 illustrates a representative set of flux lines generated by a single eddy current sensor 50 as used in prior art thickness measurement devices. The eddy current sensor generates a pattern of magnetic flux lines. The test object intersects a plurality of the flux lines at a given spacing from the eddy current sensor. If the test object 22 is inadvertently moved toward or away from the eddy current sensor, the number of flux lines intersected by the test object can change significantly even for small movements of the test object. As the number of flux lines intersected by the test object changes, so does the measurement reading of the eddy current sensor, reducing its accuracy.

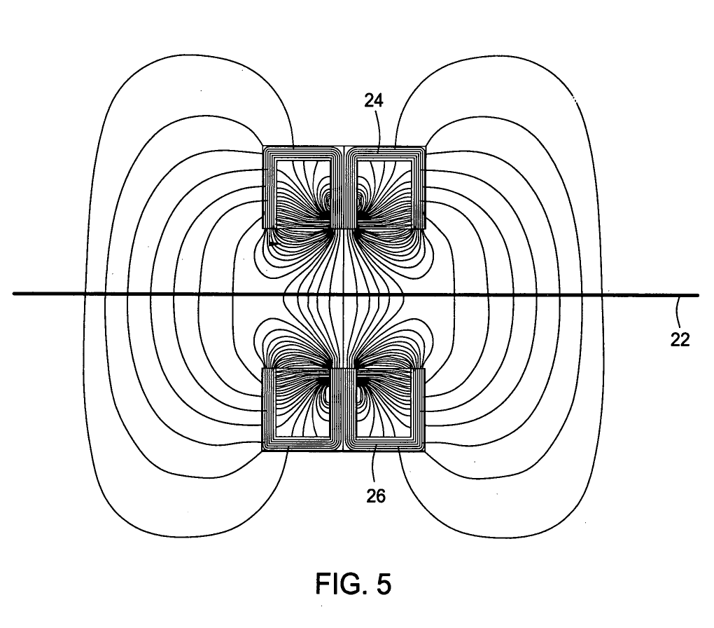

FIG. 5 illustrates a representative set of flux lines generated by the dual eddy current sensor heads 24, 26 used in devices 20 in accordance with the various embodiments described above. As shown, the test object 22 can be moved toward or away from respective sensor heads 24, 26 with a significantly reduced change in the number of flux lines intersected. Accordingly, the device has reduced sensitivity to variations in distance between the test object and the eddy current sensor heads.

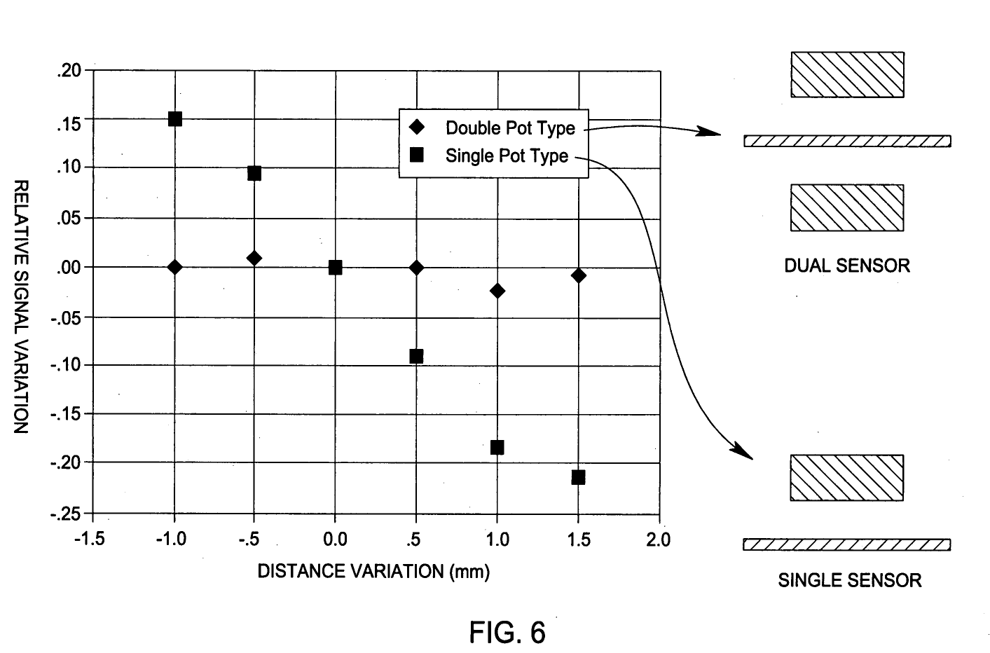

FIG. 6 illustrates an example of the differences in sensitivity to distance variations measured for two devices 24, 26, one having a single eddy current sensor head and the other having dual eddy current sensor heads. The dimensions shown in FIG. 6 for the size of the sensors are provided by way of example only. These dimensions can vary depending on the particular application.

To even further increase accuracy of thickness measurements, the Z-axis sensor can be used to compensate for inadvertent movement of the test object in a direction between the sensor heads. The Z-axis sensor 36 can detect the distance between the test object 22 and the eddy current sensor 24, 26 heads to determine a distance-related compensation factor to be applied to the raw data generated by the sensors to compensate for distance and vibration effects.

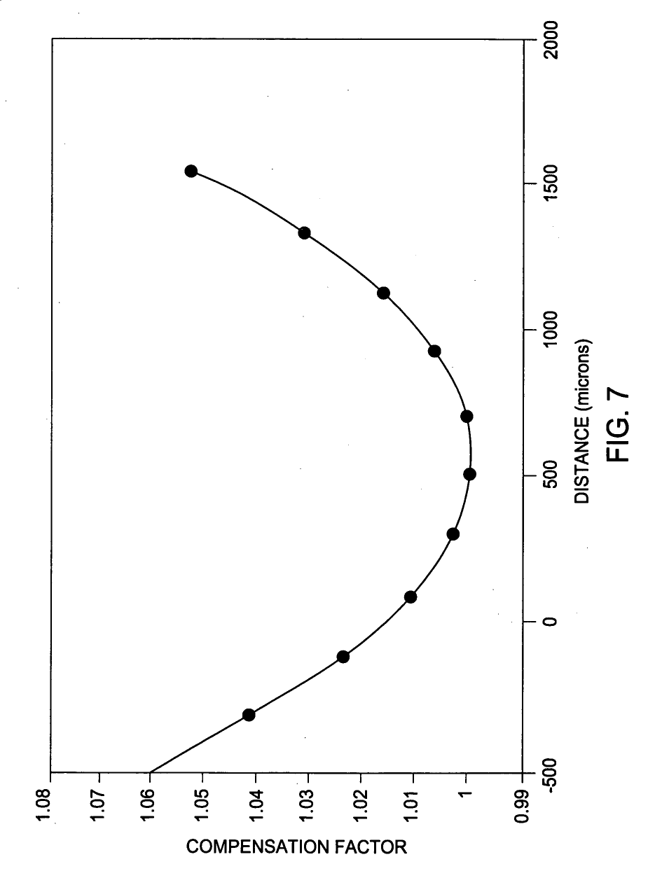

FIG. 7 is a graph illustrating representative compensation values that can be selected based on the distance moved by the test object relative to the sensor heads. The values in the graph were empirically determined, and can vary based on the device used and the object being measured.

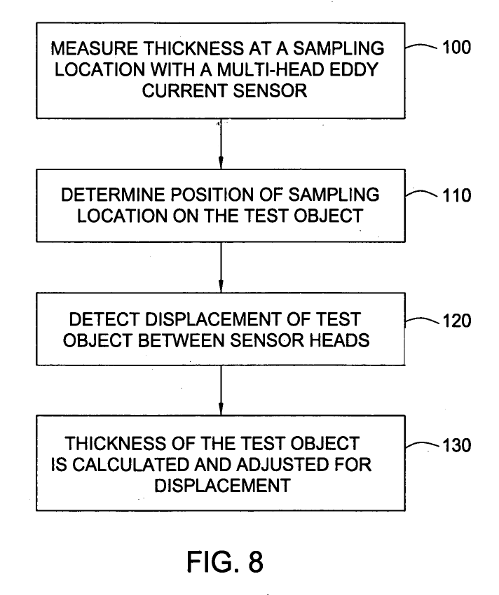

FIG. 8 is a flow chart generally illustrating a process for measuring the thickness of a test object in accordance with one or more embodiments of the invention. At step 100, a thickness measurement of the test object is made at a sampling location on the test object using first and second eddy current sensor heads positioned on opposite sides of the test object while moving the test object past the eddy current sensor heads. At step 110, the position of the sampling location on the test object is determined. At step 120, any displacement of the test object in a direction generally extending between the first and second sensor heads is detected. At step 130, the thickness of the test object at the sampling location is calculated and adjusted, if needed, to compensate for any detected displacement of the test object.

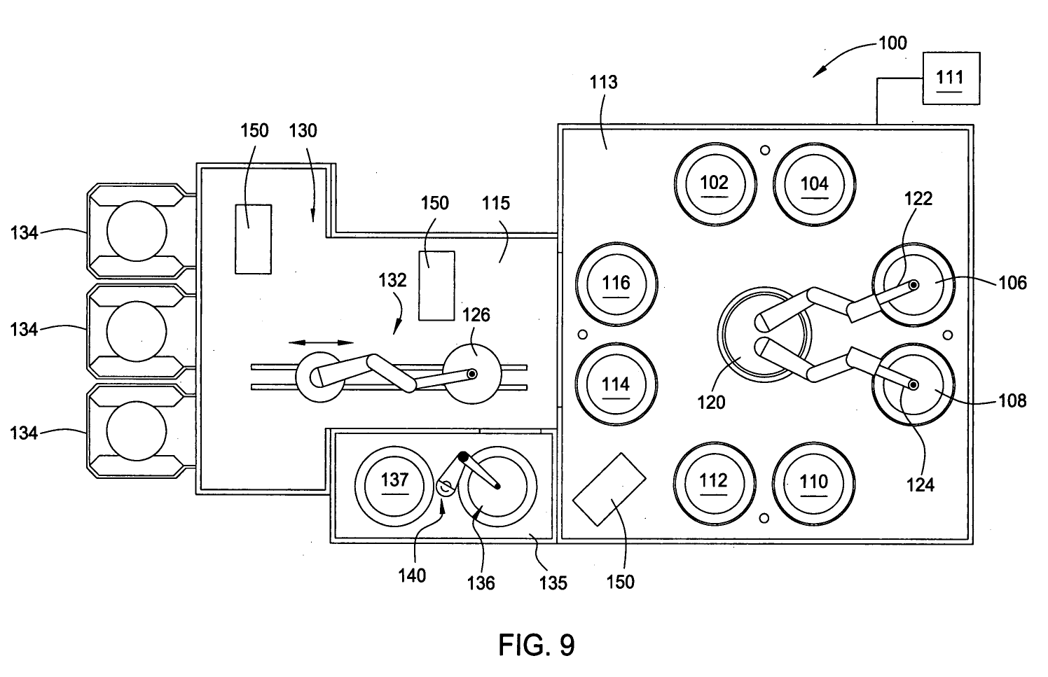

FIG. 9 illustrates a top plan view of an exemplary ECP system 100 of the invention. ECP system 100 includes a factory interface 130, which is also generally termed a substrate loading station. Factory interface 130 includes a plurality of substrate loading locations configured to interface with substrate containing cassettes 134. A robot 132 is positioned in factory interface 130 and is configured to access substrates contained in the cassettes 134. Further, robot 132 also extends into a link tunnel 115 that connects factory interface 130 to processing mainframe or platform 113. The position of robot 132 allows the robot to access substrate cassettes 134 to retrieve substrates therefrom and then deliver the substrates to one of the processing cells 114, 116 positioned on the mainframe 113, or alternatively, to the annealing station 135 or to a substrate inspection station 150. Similarly, robot 132 may be used to retrieve substrates from the processing cells 114, 116 or the annealing chamber 135 after a substrate processing sequence is complete. In this situation robot 132 may deliver the substrate to the inspection station 150 or back to one of the cassettes 134 for removal from system 100.

The anneal station 135 generally includes a two position annealing chamber, wherein a cooling plate/position 136 and a heating plate/position 137 are positioned adjacently with a substrate transfer robot 140 positioned proximate thereto, e.g., between the two stations. The robot 140 is generally configured to move substrates between the respective heating plates 137 and cooling plates 136. Further, although the anneal chamber 135 is illustrated as being positioned such that it is accessed from the link tunnel 115, embodiments of the invention are not limited to any particular configuration or placement. As such, the anneal station 135 may be positioned in direct communication with the mainframe 113, i.e., accessed by mainframe robot 120, or alternatively, the annealing station 135 may be position in communication with the mainframe 113, i.e., the annealing station may be positioned on the same system as mainframe 113, but may not be in direct contact with the mainframe 113 or accessible from the mainframe robot 120. For example, the anneal station 135 may be positioned in direct communication with the link tunnel 115, which allows for access to mainframe 113, and as such, the anneal chamber 135 is illustrated as being in communication with the mainframe 113.

As mentioned above, ECP system 100 also includes a processing mainframe 113 having a substrate transfer robot 120 centrally positioned thereon. Robot 120 generally includes one or more arms/blades 122, 124 configured to support and transfer substrates thereon. Additionally, the robot 120 and the accompanying blades 122, 124 are generally configured to extend, rotate, and vertically move so that the robot 120 may insert and remove substrates to and from a plurality of processing cells 102, 104, 106, 108, 110, 112, 114, 116 positioned on the mainframe 113. Similarly, factory interface robot 132 also includes the ability to rotate, extend, and vertically move its substrate support blade, while also allowing for linear travel along the robot track that extends from the factory interface 130 to the mainframe 113. Generally, process cells 102, 104, 106, 108, 110, 112, 114, 116 may be any number of processing cells utilized in an electrochemical plating platform. More particularly, the process cells may be configured as electrochemical plating cells, rinsing cells, bevel clean cells, spin rinse dry cells, substrate surface cleaning cells (which collectively includes cleaning, rinsing, and wet etching cells), electroless plating cells, metrology inspection stations, and/or other processing cells that may be beneficially used in conjunction with a plating platform. Each of the respective processing cells and robots are generally in communication with a process controller 111, which may be a microprocessor-based control system configured to receive inputs from both a user and/or various sensors positioned on the system 100 and appropriately control the operation of system 100 in accordance with the inputs.

In the exemplary plating system illustrated in FIG. 9, the processing cells may be configured as follows. Processing cells 114 and 116 may be configured as an interface between the wet processing stations on the mainframe 113 and the dry processing regions in the link tunnel 115, annealing chamber 135, and the factory interface 130. The processing cells located at the interface locations may be spin rinse dry cells and/or substrate cleaning cells. More particularly, each of cells 114 and 116 may include both a spin rinse dry cell and a substrate cleaning cell in a stacked configuration. Cells 102, 104, 110, and 112 may be configured as plating cells, either electrochemical plating cells or electroless plating cells, for example. Cells 106, 108 may be configured as substrate bevel cleaning cells. Additional configurations and implementations of an electrochemical processing system are illustrated in commonly assigned U.S. patent application Ser. No. 10/435,121 filed on Dec. 19, 2002 entitled “Multi-Chemistry Electrochemical Processing System”, which is incorporated herein by reference in its entirety.

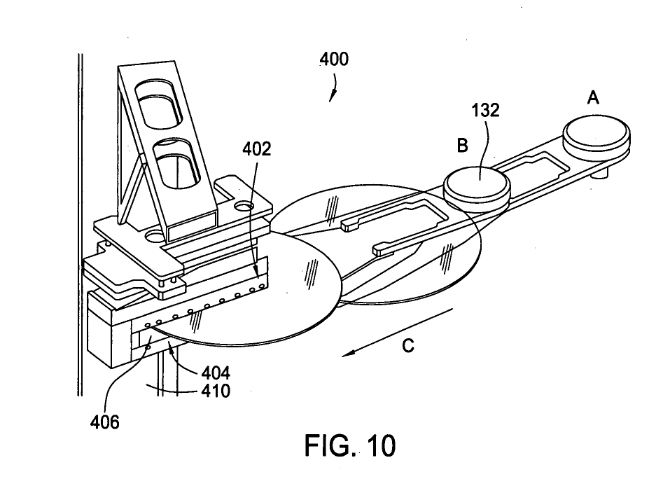

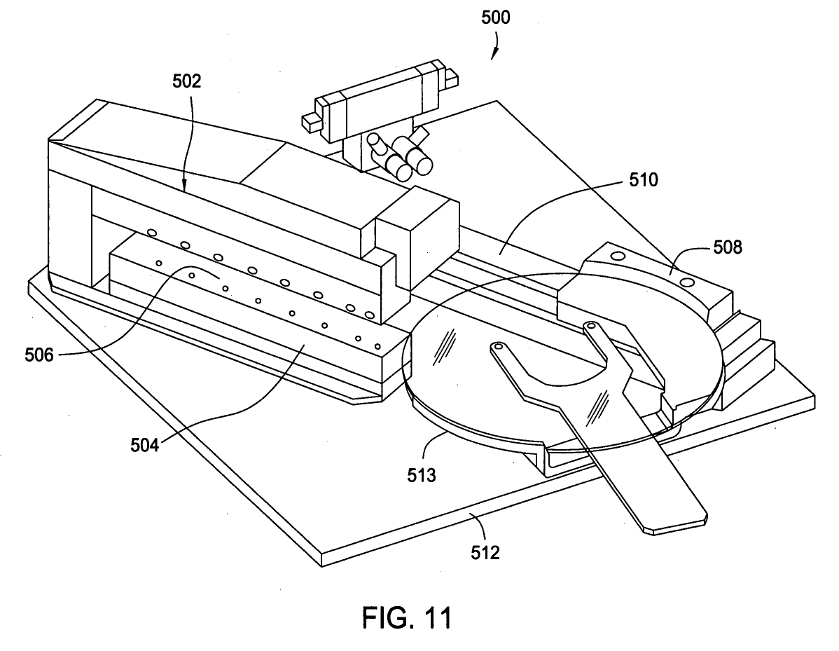

FIG. 10 illustrates a perspective view of an exemplary substrate inspection station 400 that may be implemented onto the processing system 100 of the invention. Inspection station 400 generally includes a structure shaped to receive a portion of a substrate therein, and more particularly, station 400 may include a top portion 402 and a bottom portion 404 that is spaced from the top portion 402. The spacing between the top 402 and the bottom 404 generally defines a substrate receiving slot 406. In this configuration sensors and/or analysis devices may be positioned in either the top 402 or bottom 404 portions, such that the sensors/analysis devices may be directed toward a substrate inserted into the slot 406. Station 400 may be positioned in the factory interface 130, the link tunnel 115, or on the processing mainframe 113, for example. The inspection station 400 is generally in electrical communication with the system controller 111, and as such, the inspection station 400 is configured to measure a substrate under the control of the system controller 111, and further, the inspection station is configured to transmit information representative of the measurements to the system controller 111 for use in controlling future processing steps. This feature is particularly useful in controlling a seed layer repair process in an electrochemical plating cell, for example, as the thickness of the seed layer may be measured prior to the substrate beginning the plating process. The measured pre-plating thickness of the seed layer may then be used, i.e., fed forward to the plating cell controller (controller 111) and used to appropriately control the plating process to develop or deposit on the seed layer to increase its thickness to a desired thickness.

A substrate may be inserted into slot 406 by a substrate transport robot, such as robot 132, for example. FIG. 10 illustrates a substrate insertion sequence where a robot arm 132 is first positioned at location “A”, which is outside of the slot 406. The robot arm 132 is then actuated in the direction of arrow “C” to insert the substrate into the slot 406 when the robot arm 132 reaches location “B”. In this configuration, sensors positioned on the upper 402 or lower 404 portions of the inspection station 400 are exposed to a radius of the substrate for measurement.

FIG. 11 illustrates another embodiment of an inspection station 500 of the invention. Station 500 includes a base member 512 having the inspection apparatus mounted thereon. The inspection apparatus generally includes a top portion 502 and a bottom portion 504 spaced from the top portion 502 a distance sufficient to receive a substrate therein. More particularly, the top 502 and bottom portion 504 are spaced such that a substrate may be inserted therein to a point where the center of the substrate is within the slot 506 formed by the spacing between the top 502 and bottom 504 portions. Station 500 also includes a substrate carrier assembly 508. Carrier assembly generally includes a substrate support blade 513 that is attached to a movable carriage 508. Carriage 508 is generally movable positioned on a linear track 510 that is configured to cause a substrate positioned on the blade 513 to be inserted into slot 506 for measurements. Station 500 may be positioned, for example, in the factory interface 130 or link tunnel 115 of platform 100 illustrated in FIG. 1. More particularly, station 500 may be positioned in the anneal frame member 301 at location 160. Alternatively, station 500 may be positioned on mainframe 113. In similar fashion, the inspection station 400 is generally in electrical communication with the system controller 111, and as such, the inspection station 500 is configured to measure a substrate under the control of the system controller 111, and further, the inspection station is configured to transmit information representative of the measurements to the system controller 111 for use in controlling future processing steps, such as a seed layer repair step, for example.

The substrate inspection stations 400, 500 of the invention generally utilize eddy current measurement processes to determine the thickness of a layer deposited on a substrate. As such, either the top or bottom portion of the respective inspection stations will include eddy current sensors, i.e., if the layer to be measured is positioned face up, then the sensors will be in the top portion, and conversely, if the layer to be measured is positioned face down, then the sensors will correspondingly be positioned in the lower portion of the inspection station.

Generally, eddy current sensors operate at a frequency configured to penetrate all conductive films, which generally includes the dielectric layers positioned between the conductive films. This is a distinction from conventional four point probe eddy current measurement devices, as the probe measurement devices measure only the top conductive layer when there is a dielectric layer under the conductive layer. This inherent property of four point probe measurement leads to inaccuracy in instances where the sheet resistance is not significantly greater than the conductive film resistance. For P+ doped layers, for example, substrate compensation is required. The eddy current sensors of the inspection stations of the invention operate similarly to conventional four point probe apparatuses in that they also measure the sheet resistance of the film. Once the sheet resistance of a film is determined, the thickness of the film may be derived from known mathematical methods.

However, since film resistivity is known to change with film temperature, embodiments of the invention contemplate measuring the sheet resistance of the films either before an annealing step, or alternatively, after an annealing step and after the film has had sufficient time to cool to a temperature where accurate and stable measurements may be taken. In instances where a post anneal measurement must be taken without cooling time sufficient to stabilize the film resistivity, then point to point temperature compensation may be required if accurate measurements are to be obtained.

Eddy current sensors are desirable for use in the inspection stations of the invention, as the sensors are cost effective, are capable of accurate measurements, and provide repeatable results. Eddy current sensors operate to determine the sheet resistance of a conductive film by creating a time varying magnetic field from a coil via application of an alternating current to the coil. The application of the current to the coil causes the coil to radiate energy, e.g., generates a circulating magnetic field. This magnetic field generates eddy currents in the conductive layer or film on the substrate when the magnetic field intersects the conductive surface. The eddy current generated in the conductive film in turn generates its own magnetic field, which inherently interacts with the magnetic field of the coil. This interaction causes a disturbance or change in the magnetic field of the coil and its corresponding electrical parameters, i.e., the impedance of the coil. This change of impedance can be directly measured and is known to be directly proportional to the thickness of the conductive layer.

In the exemplary plating system of the invention, the inspection station may be used to analyze or determine the thickness of a conductive layer on the substrate. The determined thickness may then be fed forward to one of the plating cells and used to control the plaitng process. More particularly, a plating cell may be configured with a plurality of anodes that are individually controlled during a plating process. In this configuration, the determined thickness may be used to determine the power application to each of the anodes during the plating process in order to deposit a layer having a substantially uniform thickness.

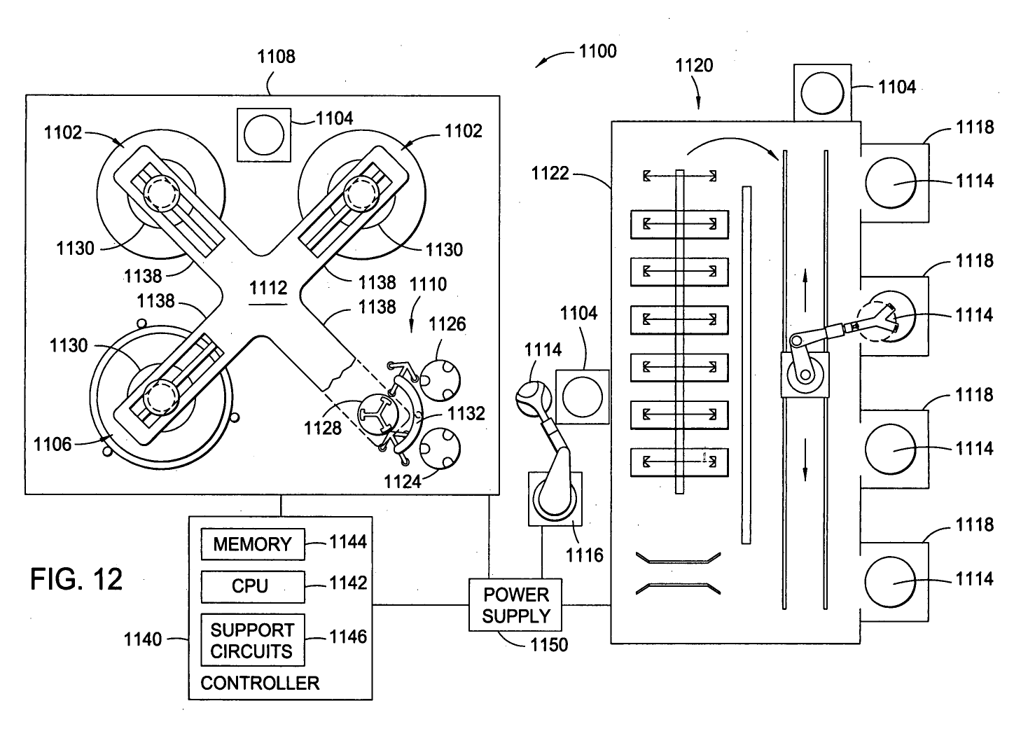

FIG. 12 illustrates another embodiment of the invention, wherein an inspection station 1104 is implemented onto a substrate polishing system 1100. Processing system 1100 includes at least one station suitable for electrochemical deposition and/or chemical mechanical polishing, such as electrochemical mechanical polishing (ECMP) station 1102 and at least one conventional polishing or buffing station 1106 disposed on a single platform or tool. One polishing tool that may be adapted to benefit from the invention is a MIRRA® Mesa™ chemical mechanical polisher available from Applied Materials, Inc. located in Santa Clara, Calif. For example, in the apparatus 1100 shown in FIG. 12, the apparatus 1100 includes two ECMP stations 1102 and one polishing station 1106. The stations may be used for processing a substrate surface. For example, a substrate having feature definitions formed therein and filled with a barrier layer and then a conductive material disposed over the barrier layer may have the conducive material removed in two steps in the two ECMP stations 102 with the barrier layer polished in the polishing station 106 to form a planarized surface. Further, system 1100 may include conventional chemical mechanical polishing stations, low pressure chemical mechanical polishing stations, or other polishing and/or planarization stations that may be used in semiconductor processing.

The exemplary apparatus 1100 generally includes a base 1108 that supports one or more ECMP stations 1102, one or more polishing stations 1106, a transfer station 1110 and a carousel 1112. The transfer station 1110 generally facilitates transfer of substrates 1114 to and from the apparatus 1100 via a loading robot 1116. The loading robot 1116 typically transfers substrates 1114 between the transfer station 1110 and a factory interface 1120 that may include a cleaning module 1122, a metrology device 1104 and one or more substrate storage cassettes 1118. One example of a metrology device 1104 is a NovaScan™ Integrated Thickness Monitoring system, available from Nova Measuring Instruments, Inc., located in Phoenix, Ariz. In other embodiments of the invention the metrology device 1104 comprises an eddy current-type device configured to determine the thickness of a conductive layer on a substrate, as described herein. Further, the inspection station 1104 may be positioned at various locations on the system, as illustrated in FIG. 12. Alternatively, the loading robot 1116 (or factory interface 1120) may transfer substrates to one or more other processing tools (not shown) such as a chemical vapor deposition tool, physical vapor deposition tool, etch tool and the like.

In one embodiment, the transfer station 1110 comprises at least an input buffer station 1124, an output buffer station 1126, a transfer robot 1132, and a load cup assembly 1128. The loading robot 1116 places the substrate 1114 onto the input buffer station 1124. The transfer robot 1132 has two gripper assemblies, each having pneumatic gripper fingers that hold the substrate 1114 by the substrate's edge. The transfer robot 1132 lifts the substrate 1114 from the input buffer station 1124 and rotates the gripper and substrate 1114 to position the substrate 1114 over the load cup assembly 1128, then places the substrate 1114 down onto the load cup assembly 1128.

The carousel 1112 generally supports a plurality of polishing heads 1130, each of which retains one substrate 1114 during processing. The carousel 1112 transfers the polishing heads 1130 between the transfer station 1110, the one or more ECMP stations 1102 and the one or more polishing stations 1106. One carousel 1112 that may be adapted to benefit from the invention is generally described in U.S. Pat. No. 5,804,507, issued Sep. 8, 1998 to Tolles et al., which is hereby incorporated by reference in its entirety.

Generally, the carousel 1112 is centrally disposed on the base 1108. The carousel 1112 typically includes a plurality of arms 1138. Each arm 1138 generally supports one of the polishing heads 1130. One of the arms 1138 depicted in FIG. 12 is not shown so that the transfer station 1110 may be seen. The carousel 1112 is indexable such that the polishing head 1130 may be moved between the stations 1102, 1106 and the transfer station 1110 in a sequence defined by the user. Generally the polishing head 1130 retains the substrate 1114 while the substrate 1114 is disposed in the ECMP station 1102 or polishing station 1106. The arrangement of the ECMP stations 1106 and polishing stations 1102 on the apparatus 1100 allow for the substrate 1114 to be sequentially plated or polished by moving the substrate between stations while being retained in the same polishing head 1130. One polishing head that may be adapted to the invention is a TITAN HEAD™ substrate carrier, manufactured by Applied Materials, Inc., located in Santa Clara, Calif.

Examples of embodiments of polishing heads 1130 that may be used with the polishing apparatus 1100 described herein are described in U.S. Pat. No. 6,183,354, issued Feb. 6, 2001 to Zuniga, et al., which is hereby incorporated by reference in its entirety.

To facilitate control of the polishing apparatus 1100 and processes performed thereon, a controller 1140 comprising a central processing unit (CPU) 1142, memory 1144, and support circuits 1146, is connected to the polishing apparatus 1100. The CPU 1142 may be one of any form of computer processor that can be used in an industrial setting for controlling various drives and pressures. The memory 1144 is connected to the CPU 1142. The memory 1144, or computer-readable medium, may be one or more of readily available memory such as random access memory (RAM), read only memory (ROM), floppy disk, hard disk, or any other form of digital storage, local or remote. The support circuits 1146 are connected to the CPU 1142 for supporting the processor in a conventional manner. These circuits include cache, power supplies, clock circuits, input/output circuitry, subsystems, and the like.

Power to operate the polishing apparatus 1100 and/or the controller 1140 is provided by a power supply 1150. Illustratively, the power supply 1150 is shown connected to multiple components of the polishing apparatus 1100, including the transfer station 1110, the factory interface 1120, the loading robot 1116 and the controller 1140. In other embodiments separate power supplies are provided for two or more components of the polishing apparatus 1100.

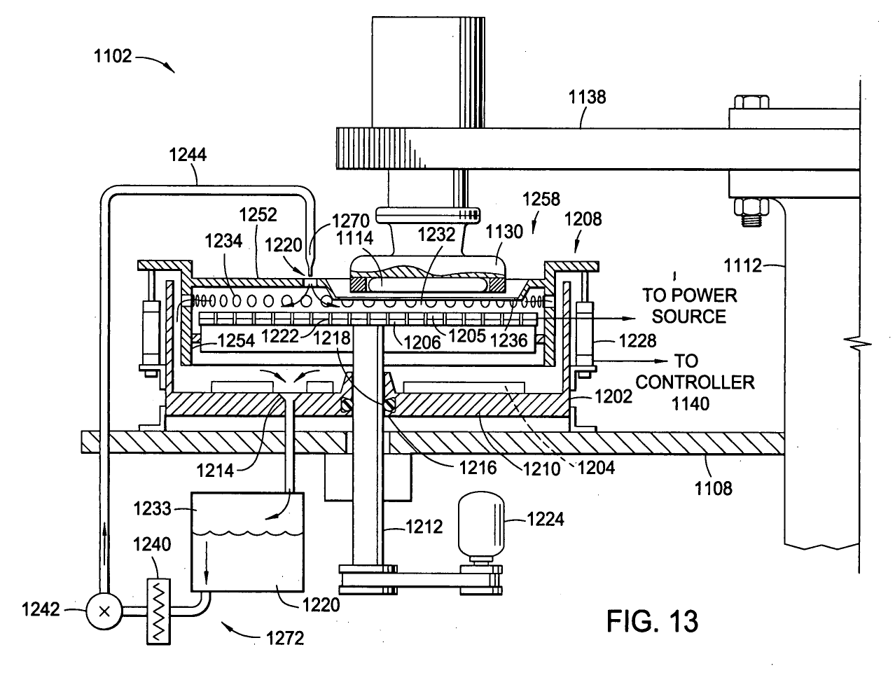

FIG. 13 depicts a sectional view of the polishing head 1130 supported above an ECMP station 1102. The ECMP station 1102 generally includes a basin 1202, an electrode 1204, polishing article 1205, a disc 1206 and a cover 1208. In one embodiment, the basin 1202 is coupled to the base 1108 of the polishing apparatus 1100. The basin 1202 generally defines a container or electrolyte cell in which a conductive fluid such as an electrolyte 1220 can be confined. The electrolyte 1220 used in processing the substrate 1114 can be used to process metals such as copper, aluminum, tungsten, gold, silver, or any other materials that can be electrochemically deposited onto or electrochemically removed from the substrate 1114.

The basin 1202 can be a bowl shaped member made of a plastic such as fluoropolymers, polytetrafluoroethylene, PFA, PE, PES, or other materials that are compatible with electroplating and electropolishing chemistries. The basin 1202 has a bottom 1210 that includes an aperture 1216 and a drain 1214. The aperture 1216 is generally disposed in the center of the bottom 1210 and allows a shaft 1212 to pass therethrough. A seal 1218 is disposed between the aperture 1216 and the shaft 1212 and allows the shaft 1212 to rotate while preventing fluids disposed in the basin 1202 from passing through the aperture 1216.

The basin 1202 typically includes the electrode 1204, the disc 1206, and the polishing article 1205 disposed therein. Polishing article 1205, such as a polishing pad, is disposed and supported in the basin 1202 on the disc 1206.

The electrode 1204 is a counter-electrode to the substrate 1114 and/or polishing article 1205 contacting a substrate surface. The polishing article 1205 is at least partially conductive and may act as an electrode in combination with the substrate during electrochemical processes, such as an electrochemical mechanical plating process (ECMPP), which includes electrochemical deposition and chemical mechanical polishing, or electrochemical dissolution. The electrode 1204 may be an anode or cathode depending upon the positive bias (anode) or negative bias (cathode) applied between the electrode 1204 and a polishing article.

For example, depositing material from an electrolyte on the substrate surface, the electrode 1204 acts as an anode and the substrate surface and/or polishing article 1205 acts as a cathode. When removing material from a substrate surface, such as by dissolution from an applied bias, the electrode 1204 functions as a cathode and the substrate surface and/or polishing article 1205 may act as an anode for the dissolution process.

The electrode 1204 is generally positioned between the disc 1206 and the bottom 1210 of the basin 1202 where it may be immersed in or exposed to the electrolyte 1220. The electrode 1204 may be fabricated from a magnetically coupled material to allow for the electrode to be secured to the platen. The electrode 1204 can be a plate-like member, a plate having multiple apertures formed therethrough, or a plurality of electrode pieces disposed in a permeable membrane or container. A permeable membrane (not shown) may be disposed between the disc 1206 and the electrode 1204 or electrode 1204 and polishing article 1205 to filter bubbles, such as hydrogen bubbles, the wafer surface and to reduce defect formation and stabilize or more uniformly apply current or power therebetween.

For electrodeposition processes, the electrode 1204 is made of the material to be deposited or removed, such as copper, aluminum, gold, silver, tungsten and other materials which can be electrochemically deposited on the substrate 1114. For electrochemical removal processes, such as anodic dissolution, the electrode 1204 may include a non-consumable electrode of a material other than the deposited material, for example, platinum, carbon, or aluminum, for copper dissolution.

The polishing article 1205 can be a pad, a web or a belt of material, which is compatible with the fluid environment and the processing specifications. In the embodiment depicted in FIG. 13, the polishing article 1205 is circular in form and positioned at an upper end of the basin 1202, supported on its lower surface by the disc 1206. The polishing article 1205 includes at least a partially conductive surface of a conductive material, such as one or more conductive elements, for contact with the substrate surface during processing. The polishing article 1205 may be a portion or all of a conductive polishing material or a composite of a conductive polishing material embedded in or disposed on a conventional polishing material. For example the conductive material may be disposed on a “backing” material disposed between the disc 1206 and polishing article 1205 to tailor the compliance and/or durometer of the polishing article 1205 during processing.

The basin 1202, the cover 1208, and the disc 1206 may be movably disposed on the base 1108. The basin 1202, cover 1208 and disc 1206 may be axially moved toward the base 1108 to facilitate clearance of the polishing head 1130 as the carousel 1112 indexes the substrate 1114 between the ECMP and polishing stations 1102, 1106. The disc 1206 is disposed in the basin 1202 and coupled to the shaft 1212. The shaft 1212 is generally coupled to a motor 1224 disposed below the base 1108. The motor 1224, in response to a signal from the controller 1140, rotates the disc 1206 at a predetermined rate.

The disc 1206 may be a perforated article support made from a material compatible with the electrolyte 1220 which would not detrimentally affect polishing. The disc 1206 may be fabricated from a polymer, for example fluoropolymers, PE, polytetrafluoroethylene, PFA, PES, HDPE, UHMW or the like. The disc 1206 can be secured in the basin 1202 using fasteners such as screws or other means such as snap or interference fit with the enclosure, being suspended therein and the like. The disc 1206 is preferably spaced from the electrode 1204 to provide a wider process window, thus reducing the sensitivity of depositing material and removing material from the substrate surface to the electrode 1204 dimensions.

The disc 1206 is generally permeable to the electrolyte 1220. In one embodiment, the disc 1206 includes a plurality of perforations or channels 1222 formed therein. Perforations include apertures, holes, openings, or passages formed partially or completely through an object, such as the polishing article. The perforation size and density is selected to provide uniform distribution of the electrolyte 1220 through the disc 1206 to the substrate 1114.

One aspect of the disc 1206 includes perforations having a diameter between about 0.02 inches (0.5 millimeters) and about 0.4 inches (10 mm). The perforations may have a perforation density between about 20% and about 80% of the polishing article. A perforation density of about 50% has been observed to provide electrolyte flow with minimal detrimental effects to polishing processes. Generally, the perforations of the disc 1206 and the polishing article 1205 are aligned to provide for sufficient mass flow of electrolyte through the disc 1206 and polishing article 1205 to the substrate surface. The polishing article 1205 may be disposed on the disc 1206 by a mechanical clamp or conductive adhesive.

While the polishing articles described herein are for electrochemical-mechanical polishing (ECMP) processes, the invention contemplates using the conductive polishing article in other fabrication processes involving electrochemical activity. Examples of such processes using electrochemical activity include electrochemical deposition, which involves the polishing article 1205 being used to apply a uniform bias to a substrate surface for depositing a conductive material without the use of conventional bias application apparatus, such as edge contacts, and electrochemical mechanical plating processes (ECMPP) that include a combination of electrochemical deposition and chemical mechanical polishing.

In operation, the polishing article 1205 is disposed on the disc 1206 in an electrolyte in the basin 1202. A substrate 1114 on the polishing head is disposed in the electrolyte and contacted with the polishing article 1205. Electrolyte is flowed through the perforations of the disc 1206 and the polishing article 1205 and is distributed on the substrate surface by grooves formed therein. Power from a power source is then applied to the conductive polishing article 1205 and the electrode 1204, and conductive material, such as copper, and the electrolyte is then removed by an anodic dissolution method.

The electrolyte 1220 is flowed from a reservoir 1233 into the volume 1232 via a nozzle 1270. The electrolyte 1220 is prevented from overflowing the volume 1232 by a plurality of holes 1234 disposed in a skirt 1254. The holes 1234 generally provide a path through the cover 1208 for the electrolyte 1220 exiting the volume 1232 and flowing into the lower portion of the basin 1202. At least a portion of the holes 1234 are generally positioned between a lower surface 1236 of the depression 1258 and the center portion 1252. As the holes 1234 are typically higher than the lower surface 1236 of the depression 1258, the electrolyte 1220 fills the volume 1232 and is thus brought into contact with the substrate 1114 and polishing medium 1205. Thus, the substrate 1114 maintains contact with the electrolyte 1220 through the complete range of relative spacing between the cover 1208 and the disc 1206.

The electrolyte 1220 collected in the basin 1202 generally flows through the drain 1214 disposed at the bottom 1210 into the fluid delivery system 1272. The fluid delivery system 1272 typically includes the reservoir 1233 and a pump 1242. The electrolyte 1220 flowing into the fluid delivery system 1272 is collected in the reservoir 1233. The pump 1242 transfers the electrolyte 1220 from the reservoir 1233 through a supply line 1244 to the nozzle 1270 where the electrolyte 1220 recycled through the ECMP station 1102. A filter 1240 is generally disposed between the reservoir 1233 and the nozzle 1270 to remove particles and agglomerated material that may be present in the electrolyte 1220.

Electrolyte solutions may include commercially available electrolytes. For example, in copper containing material removal, the electrolyte may include sulfuric acid based electrolytes or phosphoric acid based electrolytes, such as potassium phosphate (K₃PO₄), or combinations thereof. The electrolyte may also contain derivatives of sulfuric acid based electrolytes, such as copper sulfate, and derivatives of phosphoric acid based electrolytes, such as copper phosphate. Electrolytes having perchloric acid-acetic acid solutions and derivatives thereof may also be used.

Additionally, the invention contemplates using electrolyte compositions conventionally used in electroplating or electropolishing processes, including conventionally used electroplating or electropolishing additives, such as levelers, suppressors, accelerators, etc., among others. One source for electrolyte solutions used for electrochemical processes such as copper plating, copper anodic dissolution, or combinations thereof is Shipley Leonel, a division of Rohm and Haas, headquartered in Philadelphia, Pa., under the tradename Ultrafill 2000. An example of a suitable electrolyte composition is described in U.S. patent application Ser. No. 10/038,066, filed on Jan. 3, 2002, which is incorporated by reference in its entirety.

Electrolyte solutions are provided to the electrochemical cell to provide a dynamic flow rate on the substrate surface or between the substrate surface and an electrode at a flow rate up to about 20 gallons per minute (GPM), such as between about 0.5 GPM and about 20 GPM, for example, at about 2 GPM. It is believed that such flow rates of electrolyte evacuate polishing material and chemical by-products from the substrate surface and allow refreshing of electrolyte material for improved polishing rates.

When using mechanical abrasion in the polishing process, the substrate 1114 and polishing article 1205 are rotated relative to one another to remove material from the substrate surface. Mechanical abrasion may be provided by physical contact with both conductive polishing materials and conventional polishing materials as described herein. The substrate 1114 and the polishing article 1205 are respectively rotated at about 5 rpms or greater, such as between about 10 rpms and about 50 rpms.

In one embodiment, a high rotational speed polishing process may be used. The high rotational speed process includes rotating the polishing article 1205 at a platen speed of about 150 rpm or greater, such as between about 150 rpm and about 750 rpm; and the substrate 1114 may be rotated at a rotational speed between about 150 rpm and about 500 rpm, such as between about 300 rpm and about 500 rpm. Further description of a high rotational speed polishing process that may be used with the polishing articles, processes, and apparatus described herein is disclosed in U.S. patent application Ser. No. 60/308,030, filed on Jul. 25, 2001, and entitled, “Method And Apparatus For Chemical Mechanical Polishing Of Semiconductor Substrates.” Other motion, including orbital motion or a sweeping motion across the substrate surface, may also be performed during the process.

When contacting the substrate surface, a pressure of about 6 psi or less, such as about 2 psi or less is applied between the polishing article 1205 and the substrate surface. If a substrate containing low dielectric constant material is being polished, a pressure between of about 2 psi or less, such as about 0.5 psi or less is used to press the substrate 1114 against the polishing article 1205 during polishing of the substrate. In one aspect, a pressure between about 0.1 psi and about 0.2 psi may be used to polish substrates with conductive polishing articles as described herein.

In anodic dissolution, a potential difference or bias is applied between the electrode 1204, performing as a cathode, and the polishing surface 310 (See, FIG. 3) of the polishing article 1205, performing as the anode. The substrate in contact with the polishing article is polarized via a conductive polishing surface article at the same time the bias is applied to the conductive article support member. The application of the bias allows removal of conductive material, such as copper-containing materials, formed on a substrate surface. Establishing the bias may include the application of a voltage of about 15 volts or less to the substrate surface. A voltage between about 0.1 volts and about 10 volts may be used to dissolve copper-containing material from the substrate surface and into the electrolyte. The bias may also produce a current density between about 0.1 milliamps/cm² and about 50 milliamps/cm², or between about 0.1 amps to about 20 amps for a 200 mm substrate.

The signal provided by the power supply 1150 to establish the potential difference and perform the anodic dissolution process may be varied depending upon the requirements for removing material from the substrate surface. For example, a time varying anodic signal may be provided to the conductive polishing medium 1205. The signal may also be applied by electrical pulse modulation techniques. The electrical pulse modification technique comprises applying a constant current density or voltage over the substrate for a first time period, then applying a constant reverse voltage or stopping applying a voltage over the substrate for a second time period, and repeating the first and second steps. For example, the electrical pulse modification technique may use a varying potential from between about −0.1 volts and about −15 volts to between about 0.1 volts and about 15 volts.

With the correct perforation pattern and density on the polishing media, it is believed that biasing the substrate from the polishing article 1205 provides uniform dissolution of conductive materials, such as metals, into the electrolyte from the substrate surface as compared to the higher edge removal rate and lower center removal rate from conventional edge contact-pins bias.

Conductive material, such as copper-containing material, can be removed from at least a portion of the substrate surface at a rate of about 15,000 Å/min or less, such as between about 100 Å/min and about 15,000 Å/min. In one embodiment of the invention where the copper material to be removed is about 12,000 Å thick, the voltage may be applied to the conductive polishing article 1205 to provide a removal rate between about 100 Å/min and about 8,000 Å/min.

Following the electropolishing process, the substrate may be further polished or buffed to remove barrier layer materials, remove surface defects from dielectric materials, or improve planarity of the polishing process using the conductive polishing article. An example of a suitable buffing process and composition is disclosed in co-pending U.S. patent application Ser. No. 09/569,968, filed on May 11, 2000, and incorporated herein by reference in its entirety. Additional detail on the polishing apparatus, pads, zones or divisions in the pads, application of individual biases to the zones or divisions, electrodes, process applications, etc., may be found in commonly assigned U.S. patent application Ser. No. 10/608,513, filed on Jun. 26, 2003, which is hereby incorporated by reference in its entirety.

Using the multi-zone pad and the inspection station described above and in commonly assigned U.S. patent application Ser. No. 10/608,513, embodiments of the invention implement a feed forward-type of process control for a polishing process. For example, prior to a substrate being processed in the polishing apparatus of the invention, the substrate may be measured to determine the thickness of one or more layers on the substrate. The thickness measurement may be completed by any one of the inspection apparatuses or methods described herein, such as inspection station 500 or 600, for example. The measured layer thickness, which is generally taken at several points on the substrate, may then be used by the process controller to control the polishing process. More particularly, the process controller may use the measured thickness information to increase or decrease the polishing bias applied to the zones (which are illustrated as 402, 404 in the commonly assigned United States Patent Application that is incorporated by reference above) in order to compensate for variations in the thickness of layer being polished. In this way, embodiments of the invention may be used to control a polishing process on an uneven layer to be polished. More particularly, the polishing bias may be increased in the pad zones that correspond to areas of the conductive layer that are thicker than other areas of the conductive layer. This increased bias causes accelerated polishing, and as such, operates to equalize thickness of the layer being polished.

In another embodiment of the invention, the methods and processes of the invention are implemented into a low pressure chemical mechanical polishing (I-CMP) system. In I-CMP, removal is generally achieved through oxidation of the conductive layer (generally copper) at the substrate surface. The electrical bias applied between the substrate and the cathode determines the removal rate. Further, the removal results in current flow between the anode (substrate) and the cathode, which is generally positioned behind the polishing pad or in the pad itself. Previous experimentation has shown that a linear relationship exists between the current density at the substrate surface and the copper removal rate. Therefore, through monitoring the total charge, one can derive the amount of copper removal. Experimentation has also shown that dividing the cathode into multiple segments or zones that have the capability to have different electrical biases applied thereto provides a means to control the removal profile on the substrate.

Embodiments of the present invention implement real time removal profile monitoring in polishing and/or deposition processes. The monitoring and control processes of the invention require less calibration than conventional monitoring devices, as the only parameter that needs to be calibrated is the current to removal rate relationship. Further, the process of the present invention is not limited or effected by pad wear. Further, the present invention is not limited in spatial resolution and has no limitation on the thickness measurements.

The control process of the present invention may include inputs such as the rotation speed and sweep rate of the substrate during processing, the number of zones or electrodes and their shapes, the pad perforation pattern, and the locations of the thickness measurements, among other parameters. Using these parameters, if a substrate is measured and determined to be center high, then, for example, the electrode or zone that is primarily responsible for removal of material proximate the center of the substrate may have an increased removal bias applied thereto. This may be true for the edge of the substrate, for example, or a wedge or other shaped portion of the substrate. Similarly, if an area of the substrate is determined to be thin, then the corresponding zone or electrode may have a reduced bias applied thereto in order to slow the removal rate over the thinner layer.

While the foregoing is directed to embodiments of the present invention, other and further embodiments of the invention may be devised without departing from the basic scope thereof, and the scope thereof is determined by the claims that follow.

1. A method for controlling a polishing process, comprising:
determining a thickness profile of a layer to be polished;
determining a polishing profile for the layer in accordance with the determined thickness profile; and
polishing the layer in accordance with the determined polishing profile.

2. The method of claim 1, wherein polishing comprises selectively activating individual polishing zones calculated from the desired polishing profile.

3. The method of claim 2, wherein the polishing zones comprise cathode electrodes in a polishing cell.

4. A method for controlling a planarization process for a layer deposited onto a substrate, comprising:
measuring a thickness profile of the layer with an eddy current sensor;
determining a polishing profile for the layer in accordance with the measured thickness profile;
polishing the layer in a polishing cell having a plurality of polishing electrodes; and
controlling a polishing bias applied to each of the plurality polishing electrodes to generate the determined polishing profile.

5. The method of claim 4, wherein controlling the polishing electrodes comprises increasing a polishing bias applied to polishing electrodes that correspond to thicker regions of the layer.

6. The method of claim 4, wherein controlling the polishing electrodes comprises decreasing a polishing bias applied to polishing electrodes that correspond to thinner regions of the layer.

7. The method of claim 4, wherein polishing the layer comprises conducting at least one of a CMP, I-CMP, or ECMP process.
